(19) United States
(12) Patent Application Publication
(10) Pub. No.: US 2025/0056771 A1
(43) Pub. Date: Feb. 13, 2025

(54) DATACENTER LIQUID COOLING ARRANGEMENTS WITH POWER ESTIMATION AND RELATED FAN AND PUMP CONTROL

(71) Applicant: OVH, Roubaix (FR)

(72) Inventors: Ali CHEHADE, Moncheaux (FR); Mohamad HNAYNO, Roubaix (FR)

(21) Appl. No.: 18/781,669

(22) Filed: Jul. 23, 2024

(30) Foreign Application Priority Data
Aug. 7, 2023 (EP) 23306346.0

(51) Int. Cl. H05K 7/20; G05D 7/06

(52) U.S. Cl. CPC H05K 7/20836; G05D 7/0676; H05K 7/20209; H05K 7/20263; H05K 7/20281; H05K 7/20736; H05K 7/20781

(57) ABSTRACT

A liquid cooling method and system for estimating power consumption of cooling rack-mounted processing assemblies and controlling corresponding fan and pump speeds, is presented. The presented method and system provide for the estimation of the power consumption of the rack-mounted data processing assemblies by calculating a thermal load based on measured cooling liquid temperatures, heated liquid temperatures, ambient dry cooler temperatures, and cooling liquid volume and controlling the fan speed based on the estimated power consumption. The presented method and system also provide for controlling the pump speed based on measured flow rates and corresponding empirically derived pump head pressure values H.

### CROSS REFERENCE

The present application claims priority to EP Application number EP 23306346.0, filed Aug. 7, 2023, entitled “DATACENTER LIQUID COOLING ARRANGEMENTS WITH POWER ESTIMATION AND RELATED FAN AND PUMP CONTROL”, the entirety of which is incorporated herein by reference.

### FIELD

The present technology generally relates to the field of datacenter liquid cooling arrangements and, in particular, to the power estimation of datacenter rack-mounted processing assemblies and related control of cooling pumps and fans.

### BACKGROUND

Datacenters as well as many computer processing facilities house multitudes rack-mounted electronic processing equipment. In operation, such electronic processing equipment generates a substantial amount of heat that must be dissipated in order avoid electronic component failures and ensure continued efficient processing operations.

To this end, various liquid cooling measures have been implemented to facilitate the dissipation of heat generated by the electronic processing equipment. One such measure employs liquid block cooling techniques for directly cooling one or more heat-generating processing components. This technique utilizes liquid cooling blocks having internal channels that receive cooling liquid from a cooling liquid source, e.g., heat exchangers, dry coolers, municipal water supply etc., via a liquid cooling loop arrangement to circulate the cooling liquid throughout the equipment. As such, the liquid cooling blocks are positioned to be in direct thermal contact with the heat-generating components, so that the received cooling liquid absorbs the generated heat and the heated liquid is circulated, via the cooling loop arrangement, back to cooling liquid source for re-cooling.

Another liquid cooling measure employs liquid immersive cooling (IC) techniques, in which the electronic processing equipment is disposed within an immersion case containing cooling dielectric fluid. In this manner, the submerged electronic processing equipment radiates heat that is absorbed by the cooling dielectric fluid in which the heated dielectric fluid is circulated, via a cooling loop arrangement, back to cooling source for re-cooling.

Relatedly, hybrid liquid cooling measures have been introduced that employ a combination of both liquid block cooling techniques and liquid IC techniques as well as various cooling loop arrangements in efforts to maximize the cooling of electronic processing equipment.

It will be appreciated that the extent to which such cooling efforts can be realized are related to the amount of electrical power that is consumed by the electronic processing equipment.

With this said, there remains an interest in estimating the power consumed by the electronic processing equipment to control the operations of various cooling loop components to optimize cooling efficiency. Such cooling loop components include drycooler fan and pump operations.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on certain drawbacks associated with conventional dry cooling techniques and implementations.

In one aspect of the inventive concepts of the present technology a liquid cooling method for datacenter rack-mounted processing assemblies with power estimation and related drycooler fan and pump control, that comprises providing a dry cooling unit to supply a cooling liquid to the rack-mounted processing assemblies and receive a heated liquid from the rack-mounted processing assemblies, the dry cooling unit comprising a fan assembly and a heat exchanger unit; providing a first liquid distribution circuit to convey the cooling liquid from the dry cooling unit to the rack-mounted processing assemblies and a second liquid distribution circuit to convey the heated liquid from the rack-mounted processing assemblies to the dry cooling unit, the first liquid distribution circuit incorporating at least one pump along the first liquid distribution circuit to provide a pressure flow in supplying the cooling liquid from the dry cooling unit to the rack-mounted processing assemblies, in which each of the rack-mounted data processing assemblies comprising at least one heat-generating electronic processing element and at least one liquid cooling block arranged to be in respective thermal contact with the at least one heat-generating electronic processing element and fluidly-coupled to the first liquid distribution circuit and a smart control valve respectively arranged to be fluidly-coupled to the at least one liquid cooling block of the corresponding rack-mounted data processing assembly.

The liquid cooling method further provides a first temperature sensor along the first liquid distribution circuit to measure a temperature of the supplied cooling liquid T_{C}, a volume sensor to measure a flow rate of the supplied cooling liquid V_{C}, a second temperature sensor along the second liquid distribution circuit to measure a temperature of the returned heated cooling liquid T_{H}, and a third temperature sensor to measure an ambient temperature of the dry cooling unit T_{DC}.

The liquid cooling method then provides for estimating a power consumption of the rack-mounted data processing assemblies by calculating a thermal load Q of the first liquid distribution circuit based on the measured T_{C}, T_{H}, and T_{DC} values; controlling a speed of the fan assembly based on the estimated power consumption and/or ambient thermal conditions; determining whether the flow rate has increased based on the measured V_{C} value; and controlling a speed of the at least one pump based on whether the flow rate has increased.

A feature of the liquid cooling method includes controlling the fan assembly speed by evaluating the ambient temperature of the dry cooling unit T_{DC}, a current fan speed value n_{fan}, and estimated fan power consumption value Q_{fan-est}, and operating the fan assembly speed at the current fan speed value n_{fan}, and measuring actual power consumed by the fan assembly Q_{fan-real}.

Another feature of the liquid cooling method includes further controlling the fan assembly speed by determining whether the actual power consumed by the fan assembly Q_{fan-real} is greater than the estimated fan power consumption value Q_{fan-est} and a tolerance factor K_{factor} and in response to determining that Q_{fan-real} is greater than Q_{fan-est} and K_{factor}, issuing an alert message indicating that the fan assembly is overconsuming power.

An additional feature of the liquid cooling method includes controlling of the at least one pump speed by, in response to determining that the flow rate has increased, incrementally increasing the at least on pump speed nₚᵤₘₚ, determining whether the flow rate has remained the same after increasing the at least one pump speed nₚᵤₘₚ, and in response to determining that the flow rate has not increased, continue to incrementally increase the at least on pump speed nₚᵤₘₚ.

An additional feature of the liquid cooling method includes controlling of the at least one pump speed by, in response to determining that the flow rate has increased, applying a pump head H pressure value to the at least one pump corresponding to the measured flow rate.

Another feature of the liquid cooling method includes controlling of the at least one pump speed by, determining whether the applied H pressure value is less than a prescribed minimum H pressure value Hₘᵢₙ for the measured flow rate; in response to determining that the applied H pressure value is less than Hₘᵢₙ, increasing the at least one pump speed nₚᵤₘₚ; and in response to determining that the applied H pressure value is not less than Hₘᵢₙ, maintaining the previous at least one pump speed nₚᵤₘₚ.

A further feature of the liquid cooling method includes controlling of the at least one pump speed by, in response to determining that the measured flow rate has not increased, incrementally decreasing the pump speed nₚᵤₘₚ, determining whether the flow rate, based on the decreased pump speed nₚᵤₘₚ, has decreased, in response to determining that the flow rate has not decreased, continue to incrementally decrease the at least on pump speed nₚᵤₘₚ, and in response to determining that the flow rate has decreased, incrementally increasing the pump speed nₚᵤₘₚ.

And yet a further feature of the liquid cooling method includes controlling of the at least one pump speed by, applying a pump head H pressure value to the at least one pump corresponding to the measured flow rate, determining whether the applied H pressure value is less than a prescribed minimum H pressure value Hₘᵢₙ for the measured flow rate, in response to determining that the applied H pressure value is less than Hₘᵢₙ, increasing the at least one pump speed nₚᵤₘₚ, and in response to determining that the applied H pressure value is not less than Hₘᵢₙ, maintaining the previous at least one pump speed nₚᵤₘₚ.

In a related aspect of the inventive concepts, the present technology provides a liquid cooling arrangement for estimating power consumption and controlling drycooler fan operations that comprises a dry cooling unit configured to supply a cooling liquid to the rack-mounted processing assemblies and receive a heated liquid from the rack-mounted processing assemblies, the dry cooling unit comprising a fan assembly and a heat exchanger unit; a first liquid distribution circuit configured to convey the cooling liquid from the dry cooling unit to the rack-mounted processing assemblies, the first liquid distribution circuit incorporating at least one pump along the first liquid distribution circuit to provide a pressure flow in supplying the cooling liquid from the dry cooling unit to the rack-mounted processing assemblies; a second liquid distribution circuit configured to convey the heated liquid from the rack-mounted processing assemblies to the dry cooling unit, in which each of the rack-mounted data processing assemblies comprises at least one heat-generating electronic processing element, at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and a smart control valve respectively arranged to be fluidly-coupled to the at least one liquid cooling block of the corresponding rack-mounted data processing assembly, the smart control valve configured to be pressure independent and controls the flow rate of the cooling fluid of the corresponding rack-mounted data processing assembly based on detected temperatures and pressure flows.

The liquid cooling arrangement further comprises a first temperature sensor configured to measure a temperature of the supplied cooling liquid T_{C}, a volume sensor to measure a flow rate of the supplied cooling liquid V_{C}, second temperature sensor configured to measure a temperature of the returned heated cooling liquid T_{H}, a third temperature sensor configured to measure an ambient temperature of the dry cooling unit T_{DC}, and a control module, communicatively coupled to the fan assembly and the at least one pump and configured to: receive the measured T_{C}, V_{C}, T_{H}, and T_{DC} values; estimate a power consumption of the rack-mounted data processing assemblies by calculating a thermal load Q of the first liquid distribution circuit based on the measured T_{C}, T_{H}, and T_{DC} values, control a speed of the fan assembly based on the estimated power consumption and/or ambient conditions, determine whether the flow rate has increased based on the measured V_{C} value, and control a speed of the at least one pump based on whether the flow rate has increased.

An additional feature of the liquid cooling arrangement includes controlling the fan assembly speed by operating the fan assembly speed at the current fan speed value n_{fan}, and measuring actual power consumed by the fan assembly Q_{fan-real}; determining whether the actual power consumed by the fan assembly Q_{fan-real} is greater than the estimated fan power consumption value Q_{fan-est} and a tolerance factor K_{factor}, and in response to determining that Q_{fan-real} is greater than Q_{fan-est} and K_{factor}, issuing an alert message indicating that the fan assembly is overconsuming power.

Another feature of the liquid cooling arrangement includes further controlling the at least one pump speed by, in response to determining that the flow rate has decreased, decreasing the speed of the at least one pump nₚᵤₘₚ; determining whether the flow rate based on the decreased pump speed nₚᵤₘₚ has decreased; in response to determining that the flow rate has not decreased, continue to incrementally decrease the at least on pump speed nₚᵤₘₚ; in response to determining that the flow rate has decreased, incrementally increase the pump speed nₚᵤₘₚ.

A further feature of the liquid cooling arrangement includes controlling of the at least one pump speed by applying a pump head H pressure value to the at least one pump corresponding to the flow rate; determining whether the applied H pressure value is less than a prescribed minimum H pressure value Hₘᵢₙ for the measured flow rate; in response to determining that the applied H pressure value is less than Hₘᵢₙ, increasing the at least one pump speed nₚᵤₘₚ; and in response to determining that the applied H pressure value is not less than Hₘᵢₙ, maintaining the previous at least one pump speed nₚᵤₘₚ.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

Furthermore, in the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

Additionally, in the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a high-level functional block diagram of a liquid cooling system for datacenter rack-mounted processing assemblies with power estimation and related control of drycooler fans and pumps, in accordance with the nonlimiting embodiments of the present technology;

FIG. 2 illustrates a flow diagram of a power estimation and fan control process of a liquid cooling system for rack-mounted processing assemblies, in accordance with the non-limiting embodiments of the present technology;

FIG. 3 illustrates a flow diagram of a pump control process of a liquid cooling system for rack-mounted processing assemblies, in accordance with the non-limiting embodiments of the present technology;

FIG. 4 illustrates empirical curves of pump head values relative to flow rates for one and two pumps, in accordance with the non-limiting embodiments of the present technology;

FIG. 5 illustrates a flow diagram of an additional pump control process of a liquid cooling system for rack-mounted processing assemblies, in accordance with the non-limiting embodiments of the present technology; and

FIG. 6 illustrates a high-level functional block diagram of a controller for the liquid cooling system with power estimation with power estimation and related control of drycooler fans and pumps.

It should be appreciated that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the FIGS. including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

Equally noteworthy, while various operations of the inventive concepts may be represented by flowchart elements arranged in certain sequential order, it should be understood that these steps may be combined, sub-divided, re-ordered, or changed to operate concurrently without departing from the teachings of the present technology. In fact, at least some of the processing steps may be executed in parallel or in series. Accordingly, the ordering, sequencing, and grouping of the processing steps is not a limitation of the present technology.

Given this fundamental understanding, the disclosed embodiments are directed to estimating the power consumed by the electronic processing equipment to control the operations of various cooling loop components to optimize cooling efficiency. More particularly, to the control of drycooler fan and pump operations.

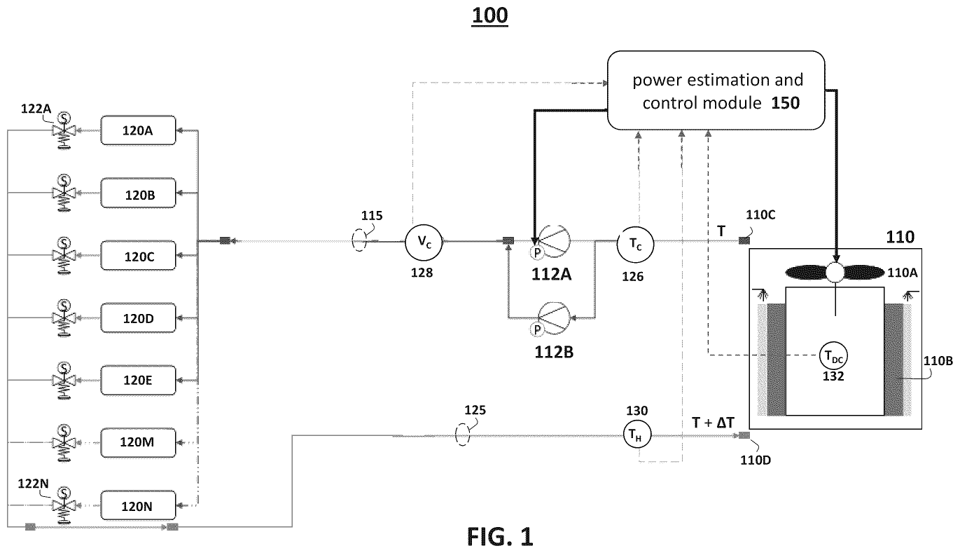

FIG. 1 illustrates the high-level functional block diagram of a liquid cooling system 100 for datacenter rack-mounted processing assemblies processing assemblies with power estimation and related control of drycooler fans and pumps, in accordance with the nonlimiting embodiments of the present technology, in accordance with the nonlimiting embodiments of the present technology.

As shown, the system 100 includes a dry cooling unit 110, a plurality of rack-mounted processing assemblies 120A-120N, a plurality of “smart” valves 122A-122N in which each smart valve is fluidly-coupled to a respective processing assembly, a forward liquid distribution circuit 115 incorporating a pump 112 for supplying cooling liquid from the dry cooling unit 110, and a return liquid distribution circuit 125 for returning heated liquid back to the dry cooling unit 110.

The dry cooling unit 110 incorporates an outlet 110C configured to supply cooling liquid and an inlet 110D configured receive heated liquid. The dry cooling unit 110 serves to dissipate thermal energy from a heated liquid circulating therethrough to the ambient environment. For example, in a datacenter or similar facility, the dry cooling unit 110 operates to receive heated liquid from the rack-mounted processing assemblies 120A-120N (e.g., water circulated through water blocks in contact with heat-generating components) and extracts the thermal energy from the heated liquid by dissipating the energy into the ambient environment via the at least one fan assembly 110A, thereby re-cooling the heated liquid. The dry cooling unit 110 then operates to supply the re-cooled liquid back to the rack-mounted processing assemblies 120A-120N.

As shown, the dry cooling unit 110 includes at least one heat exchanger 110B and at least one fan assembly 110A. The heat exchanger 110B may manifest a variety of configurations, such as, air-to-liquid heat exchanger etc., and may also include evaporating pads or cooling pads. For purposes of the instant disclosure, the exact configuration of the dry cooling unit 110 and heat exchanger 110B is not limiting, as various configurations could be employed without departing from the concepts of the instant disclosure.

The cooling/re-cooled liquid is supplied by the dry cooling unit 110 to the rack-mounted processing assemblies 120A-120N via the outlet 110C and forward liquid distribution circuit 115. The forward liquid distribution circuit 115 incorporates at least two pumps 112A, 112B arranged in a parallel configuration to maintain the flow rate of the cooling/re-cooled liquid supplied to the processing assemblies 120A-120N at an adequate level. In some implementations, the two pumps 112A, 112B are configured to operate in a master-slave configuration unless circumstances require the concurrent use of both pumps.

The heated liquid from the rack-mounted processing assemblies 120A-120N is returned back to the dry cooling unit 110 for re-cooling via the inlet 110D and return liquid distribution circuit 125. As shown, the dry cooling unit 110 supplies the cooling/re-cooled liquid to the rack-mounted processing assemblies 120A-120N at a nominal temperature T and the heated liquid returned to the dry cooling unit 110 is at a nominal temperature T+ΔT, where ΔT represents the temperature differential between the cooling/re-cooled liquid and the heated liquid.

Returning to FIG. 1, the liquid cooling system 100 includes a plurality of rack-mounted processing assemblies 120A-120N which receive the supplied cooling/re-cooled liquid via the forward liquid distribution circuit 115, internally channel the liquid to the heat-generating processing components (e.g., water circulated through water blocks), and convey the heated liquid from the heat-generating processing components to the return liquid distribution circuit 125.

The rack-mounted processing assemblies 120A-120N may or may not be configured with similar heat-generating processing components. As such, each of the rack-mounted processing assemblies 120A-120N may have different temperature and flow rate requirements for proper operations.

It will be appreciated that, while the rack-mounted processing assemblies 120A-120N are shown to be arranged in a parallel configuration, it is not meant to be limiting, as the processing assemblies 120A-120N may also be arranged in a serial or combined parallel and serial configuration without departing from the concepts of the instant disclosure.

As shown, each of the rack-mounted processing assemblies 120A-120N is fluidly-coupled to a “smart” valve 122A-122N that dynamically controls the flow rate of the corresponding processing assembly 120A-120N based on detected liquid temperatures and/or flow rates. For purposes of the instant disclosure, the term “smart” valve refers to a valve that is pressure-independent, temperature-responsive, and incorporates a differential pressure regulator to automatically adjust to system pressure changes. Such smart valves may comprise PICVs, ABQMs, or other functionally similar valves.

The liquid cooling system 100 also incorporates a temperature sensor 126 for measuring the temperature of the supplied cooling liquid T_{C} along the forward liquid distribution circuit 115, a volume sensor 128 for measuring the flow rate of the supplied cooling liquid V_{C} along the forward liquid distribution circuit 115, a temperature sensor for measuring 140 the temperature of the returned heated liquid T_{H} along the return liquid distribution circuit 125, and a temperature sensor 132 for measuring the ambient temperature of dry cooling unit T_{DC}.

Each of the measured T_{C}, V_{C}, T_{H}, and T_{DC} values are then supplied to estimating and control module 150. As will be described in detail below, based on these measured values, module 150 functions to determine the estimated power consumed by the rack-mounted processing assemblies 120A-120N and dynamically controls pressure flow rate of pumps 112A, 112B as well as the rotational speed of dry cooling unit fan assembly 110A to improve cooling system efficiency.

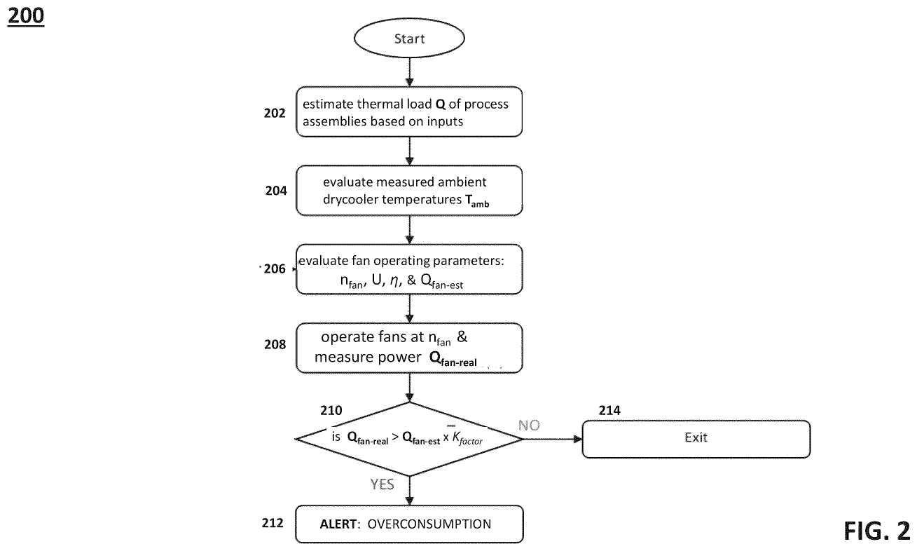

With this said, FIG. 2 illustrates a flow diagram of power estimation and fan control process 200 of a liquid cooling system for rack-mounted processing assemblies, in accordance with the non-limiting embodiments of the present technology. The power estimation and fan control process 200 may be executed by control module 150. The execution of module 150 may be performed by a controller 600.

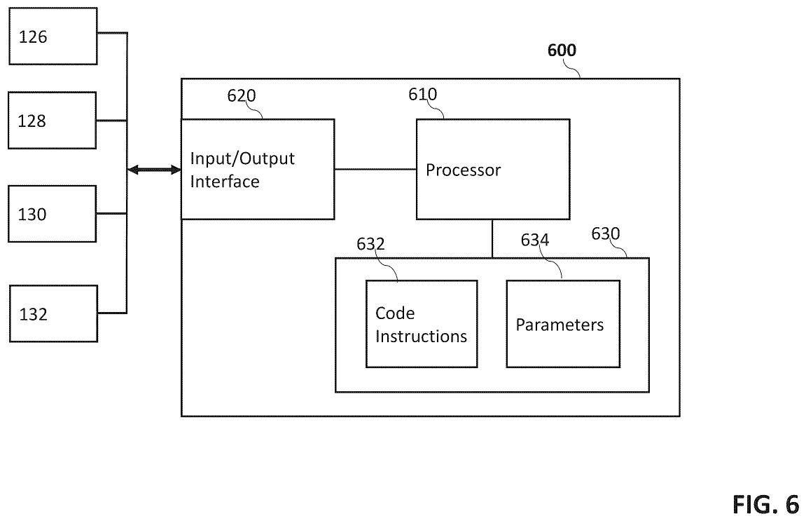

For example, such a controller is depicted by the high-level functional block diagram of FIG. 6. As shown, the controller 600 comprises a processor or a plurality of cooperating processors (represented as a processor 610 for simplicity), a memory device or a plurality of memory devices (represented as a memory device 630 for simplicity), and an input/output interface 620 (or separate input and output interfaces) allowing the controller 600 to communicate with certain components of the liquid cooling arrangement 100. The processor 610 is operatively connected to the memory device 630 and to the input/output interface 620. The memory device 630 includes a storage for storing parameters 634, including for example and without limitation the above-mentioned pre-determined conductivity thresholds. The memory device 630 may comprise a non-transitory computer-readable medium for storing code instructions 632 that are executable by the processor 610 to allow the controller 600 to perform the various tasks allocated to the controller 600.

The controller 600 is operatively connected, via the input/output interface 620, to the components of liquid cooling arrangement 100, such as, the temperature sensor 126 that measures the temperature of cooling liquid T_{C}, the temperature sensor 132 that measures the temperature of cooling liquid T_{DC}, the temperature sensor 130 that measures the temperature of heated liquid T_{H}, and the volume sensor 128 that measures the cooling liquid flow rate V_{C}, The controller 600 executes the code instructions 632 stored in the memory device 630 to implement the various above-described functions of the control module 150.

However, it will be appreciated that in other embodiments, power estimation and fan control process 200 or portions thereof may be executed by relevant components, such as, for example, temperature sensors, volume sensors, and pumps, etc. For purposes of the instant disclosure, the exact entity or entities executing process 200 is not limiting with regard to the inventive concepts herein presented.

Returning back to FIG. 2, process 200 commences at task block 202, in which the thermal load Q of the forward liquid distribution circuit 115 is estimated. The thermal load Q of the forward liquid distribution circuit 115 corresponds to the power consumed by the rack-mounted processing assemblies 120A-120N. As such, process 200 determines ΔT representative of the temperature differential between the supplied cooling liquid temperature, as measured by T_{C}, and the returning heated liquid temperature, as measured by T_{H}. Process 200 then computes the estimated thermal load Q of the forward liquid distribution circuit 115 based on the relationship: thermal load Q=m·cp·ΔT, where m represents the mass flow rate of water and cp represents the specific heat calculated as a function of the fluid average temperature.

Process 200 then moves to task block 204 to evaluate the measured ambient temperature of the dry cooling unit 110 T_{DC}, which depends on whether cooling pads are employed. Then, at task block 206, process 200 evaluates the dry cooling unit fan assembly 110A operating parameters. Such operating parameters may include, but are not limited to, fan speed n_{fan} (in rotations per minute: rpms), fan piloting voltage U (approximately between 0-10V), fan efficiency parameter η(in %), and estimated fan power consumption Q_{fan-est}. It will be appreciated that these operating parameters may be influenced by prevailing conditions, such as, for example, thermal load Q, ambient dry cooling unit temperature T_{DC}, outdoor humidity, and other factors.

Process 200 advances to task block 208, in which the actual power consumed Q_{fan-real} by the fan assembly 110A operating at n_{fan} speed (rpms) is measured. Then, at decision block 256, it is determined whether the actual power consumed by fan assembly, Q_{fan-real}, is greater than the estimated fan power consumption Q_{fan-est} multiplied by a tolerance K_{factor}. The tolerance K_{factor} value may be based on a variety of desired operational parameters or values, such as, for example, partial power usage efficiency (PPUE), acceptable power margins, etc. and in some implementations comprises approximately ±10%.

If at decision block 210 it is determined that the actual power consumed by fan assembly Q_{fan-real} is not greater than the estimated fan power consumption Q_{fan-est} and K_{factor}, then at task block 214, the process 200 exits indicative that fan assembly 110A is operating at optimal efficiency. However, if Q_{fan-real} is greater than Q_{fan-est} and K_{factor}, process 200 issues an alert message at task block 212 indicating that fan assembly 110A is not operating efficiently, due to over consumption of power.

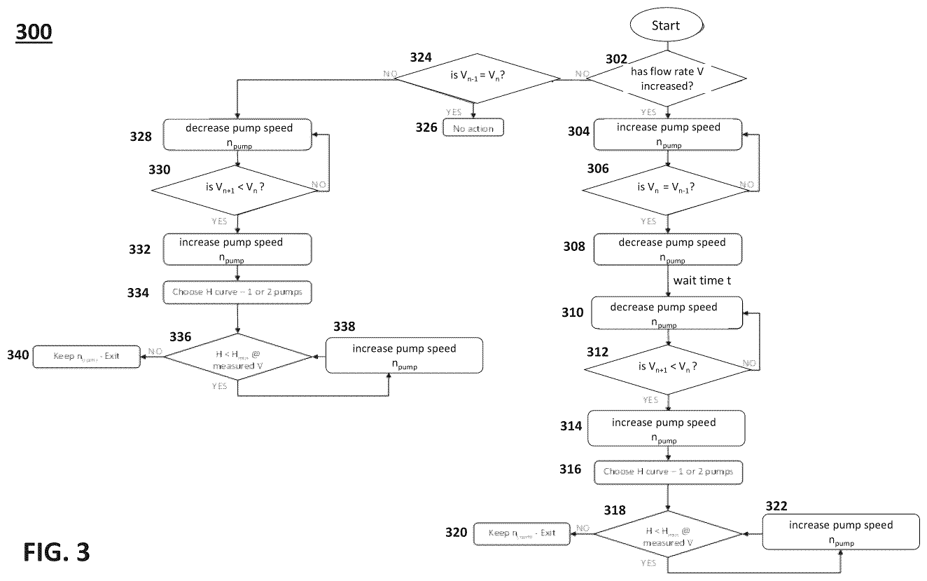

FIG. 3 illustrates a flow diagram of pump control process 300 of a liquid cooling system for rack-mounted processing assemblies, in accordance with the non-limiting embodiments of the present technology. As described above, liquid cooling system 100 implements at least two pumps 112A, 112B arranged in a parallel configuration to maintain the flow rate of the cooling/re-cooled liquid supplied to the processing assemblies 120A-120N at an adequate level.

With this said, process 300 commences at decision block 302 to determine whether the measured flow rate V_{C} of the supplied cooling liquid has increased and, if so, process 300 moves to task block 304 to incrementally increase pump speeds nₚᵤₘₚ. Then, at decision block 306, it is determined whether the flow rate Vₙ is still equal to the previous flow rate Vₙ₋₁. If it is not, then process 300 reverts back to task block 304 to further incrementally increase the pump speeds nₚᵤₘₚ.

However, if at decision block 306, it is determined that the flow rate V₁ is still equal to the previous flow rate Vₙ₋₁, then the pump speeds nₚᵤₘₚ are decreased at task block 308 and after a wait time period t, the pump speeds nₚᵤₘₚ are decreased again at task block 310. The wait time period t is based on operational parameters and in certain implementations may be set from approximately 20 seconds to approximately 45 seconds.

Process 300 then proceeds to decision block 312 to determine whether the new flow rate Vₙ₊₁ is less than the previous flow rate V₁ and if not, process 300 reverts back to task block 310 to further incrementally decrease the pump speeds nₚᵤₘₚ. However, if the new flow rate Vₙ₊₁ is less than the previous flow rate Vₙ, then process 300 incrementally increases pump speeds nₚᵤₘₚ at task block 314.

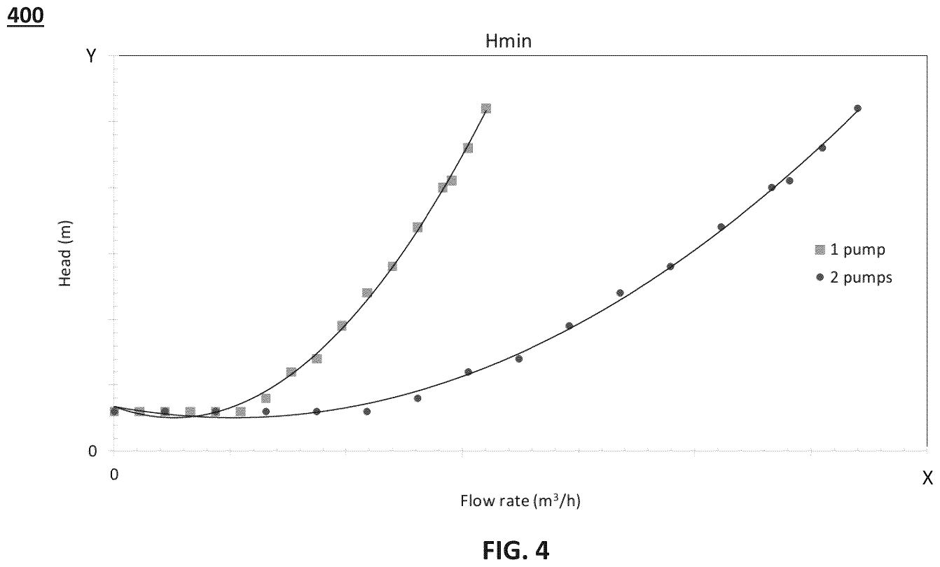

Process 300 then proceeds to task block 316 to select and apply the appropriate H values based on empirically determined pump head H curves 400 as depicted by FIG. 4, in accordance with the non-limiting embodiments of the present technology. Generally, pump head pressure values H are based on a pump's output discharge pressure minus the pump's input suction pressure. As such, the H curves represent empirical data regarding the minimum head pressure values Hₘᵢₙ required to provide the necessary pressure for given flow rates for one and two pumps. Accordingly, process 300 applies the appropriate H pressure values to the pump speed nₚᵤₘₚ based on the use of the one or two pumps 112A, 112B.

Then, after the appropriate H values are selected and applied, at decision block 318, process 300 determines whether the applied H pressure values are less than the minimum value Hₘᵢₙ for the measured flow rate V and if so, process 300 incrementally increases the pump speed nₚᵤₘₚ at task block 322. However, if the applied H pressure values are not less than the minimum value Hₘᵢₙ for the measured flow rate V, the pump speed nₚᵤₘₚ is determined to be efficient and maintained at task block 320.

Returning back to decision block 302, if it is determined that the measured flow rate V_{C} of the supplied cooling liquid has not increased, then process 300 moves to decision block 324 to determine whether V₁ is still equal to the previous flow rate Vₙ₋₁, and if so, then no further controlling action is necessary, as indicated by task block 326.

However, if at decision block 324, it is determined that Vₙ is not equal to the previous flow rate Vₙ₋₁, then process 300 moves to incrementally decrease the pump speeds nₚᵤₘₚ at task block 328. Then at decision block 330, process 300 determines whether the new flow rate Vₙ₊₁ is less than the previous flow rate Vₙ, and, if not, process 300 reverts back to task block 328 for further incremental decrease of the pump speeds nₚᵤₘₚ. However, if at decision block 330, it is determined that the new flow rate Vₙ₊₁ is less than the previous flow rate Vₙ, then process 300 moves to task block 332 to incrementally increase the pump speeds nₚᵤₘₚ.

Process 300 advances to task block 334 that selects and applies the appropriate H pressure values to the pump speed nₚᵤₘₚ based on the use of the one or two pumps 112A, 112B. Then process 300 moves to decision block 336 to determine whether the applied H pressure values are less than the minimum value Hₘᵢₙ for the measured flow rate V and if so, process 300 incrementally increases the pump speed nₚᵤₘₚ at task block 338. However, if the applied H pressure values are not less than the minimum value Hₘᵢₙ for the measured flow rate V, the pump speed nₚᵤₘₚ is determined to be efficient and maintained at task block 340.

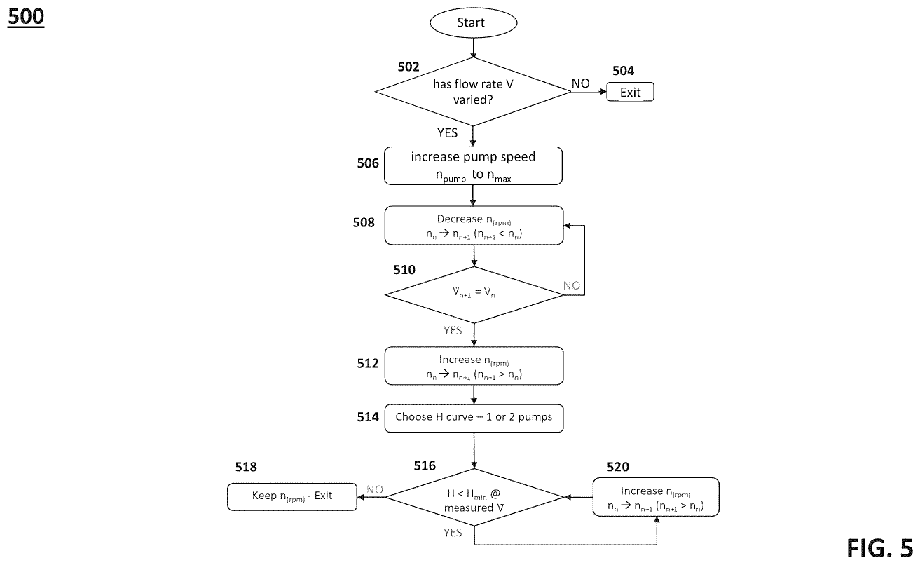

FIG. 5 illustrates a flow diagram of an additional pump control process 500 of a liquid cooling system for rack-mounted processing assemblies, in accordance with the non-limiting embodiments of the present technology. The pump control process 500 is directed to checking and handling sudden flow rate V variations during operations.

In particular, at decision block 502, process 500 checks to determine whether the flow rate V has varied (i.e., increased or decreased) during the course of operations. If not, at task block 504, process 500 exits. However, if it is determined that flow rate V has varied, at task block 506, process 500 increases the pump speed nₚᵤₘₚ to a predetermined maximum threshold level nₘₐ. Then, at process block 508, process 500 incrementally decreases the pump speeds nₚᵤₘₚ and at decision block 510 checks whether the new flow rate Vₙ₊₁ is equal to the previous flow rate Vₙ, and if not, process 500 reverts back to task block 508 to continue to incrementally decrease the pump speeds nₚᵤₘₚ.

However, if it is determined at decision block 510, that the new flow rate Vₙ₊₁ is equal to the previous flow rate Vₙ, then process 500 proceeds to incrementally increase the pump speed nₚᵤₘₚ at task block 512.

Process 500 then moves to task block 514 to select and apply the appropriate H values and, at decision block 516, process 500 determines whether the applied H pressure values are less than the minimum value Hₘᵢₙ for the measured flow rate V and if so, process 500 incrementally increases the pump speed nₚᵤₘₚ at task block 520 and returns back to decision block 516 for further checking. However, if the applied H pressure values are not less than the minimum value Hₘᵢₙ for the measured flow rate V, then the pump speed nₚᵤₘₚ is determined to be efficient and maintained at task block 518.

In this manner, the disclosed configuration and processes function to estimate the power consumed by the electronic processing equipment and accordingly control the operations of the drycooler fan assembly and pump(s) to optimize the cooling efficiency of the liquid cooling loop arrangements.

While the above-described implementations have been described and shown with reference to particular processing steps performed in a particular sequence or order, it will be understood that these steps may be combined, sub-divided, re-ordered, or changed to operate concurrently without departing from the teachings of the inventive concepts presented herein. In fact, at least some of the processing steps may be alternatively executed in parallel or in series. Accordingly, the ordering, sequencing, and grouping of the processing steps is not a limitation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A liquid cooling method for rack-mounted processing assemblies, comprising:
providing a dry cooling unit to supply a cooling liquid to the rack-mounted processing assemblies and receive a heated liquid from the rack-mounted processing assemblies, the dry cooling unit comprising a fan assembly and a heat exchanger unit;
providing a first liquid distribution circuit to convey the cooling liquid from the dry cooling unit to the rack-mounted processing assemblies and a second liquid distribution circuit to convey the heated liquid from the rack-mounted processing assemblies to the dry cooling unit, the first liquid distribution circuit incorporating at least one pump along the first liquid distribution circuit to provide a pressure flow in supplying the cooling liquid from the dry cooling unit to the rack-mounted processing assemblies;
each of the rack-mounted data processing assemblies comprising at least one heat-generating electronic processing element and at least one liquid cooling block arranged to be in respective thermal contact with the at least one heat-generating electronic processing element and fluidly-coupled to the first liquid distribution circuit and a smart control valve respectively arranged to be fluidly-coupled to the at least one liquid cooling block of the corresponding rack-mounted data processing assembly;
providing a first temperature sensor along the first liquid distribution circuit to measure a temperature of the supplied cooling liquid T_{C} and a volume sensor to measure a flow rate of the supplied cooling liquid V_{C};
providing a second temperature sensor along the second liquid distribution circuit to measure a temperature of the returned heated cooling liquid T_{H};
providing a third temperature sensor to measure an ambient temperature of the dry cooling unit T_{DC};
estimating a power consumption of the rack-mounted data processing assemblies by calculating a thermal load Q of the first liquid distribution circuit based on the measured T_{C}, T_{H}, and T_{DC} values;
controlling a speed of the fan assembly based on the estimated power consumption and/or ambient thermal conditions;
determining whether the flow rate has increased based on the measured V_{C} value; and
controlling a speed of the at least one pump based on whether the flow rate has increased.

2. The liquid cooling method of claim 1, wherein the controlling of the fan assembly speed further comprises evaluating the ambient temperature of the dry cooling unit T_{DC}, a current fan speed value n_{fan}, and estimated fan power consumption value Q_{fan-est}.

3. The liquid cooling method of claim 1, wherein the controlling of the fan assembly speed further comprises operating the fan assembly speed at the current fan speed value n_{fan}, and measuring actual power consumed by the fan assembly Q_{fan-real}.

4. The liquid cooling method of claim 2, wherein the controlling of the fan assembly speed further comprises:
determining whether the actual power consumed by the fan assembly Q_{fan-real} is greater than the estimated fan power consumption value Q_{fan-est} and a tolerance factor K_{factor} and
in response to determining that Q_{fan-real} is greater than Q_{fan-est} and K_{factor}, issuing an alert message indicating that the fan assembly is overconsuming power.

5. The liquid cooling method of claim 1, wherein the controlling of the at least one pump speed further comprises:
in response to determining that the flow rate has increased, incrementally increasing the at least on pump speed nₚᵤₘₚ;
determining whether the flow rate has remained the same after increasing the at least one pump speed nₚᵤₘₚ; and
in response to determining that the flow rate has not increased, continue to incrementally increase the at least on pump speed nₚᵤₘₚ.

6. The liquid cooling method of claim 1, wherein the controlling of the at least one pump speed further comprises that, in response to determining that the flow rate is not the same, decreasing the pump speed and after an operating wait time period t, decreasing the pump speed again.

7. The liquid cooling method of claim 1, wherein the controlling of the at least one pump speed further comprises:
determining whether the flow rate based on the decreased pump speed is less than the previous flow rate; and
in response to determining that the flow rate based on the decreased pump speed is not less than the previous flow rate, continue decreasing the pump speed.

8. The liquid cooling method of claim 1 wherein, upon determining that the flow rate based on the decreased pump speed is less than the previous flow rate, increase the pump speed and select and apply a pump head H pressure value to the at least one pump corresponding to the measured flow rate.

9. The liquid cooling method of claim 1 further comprising:
determining whether the applied H pressure value is less than a prescribed minimum H pressure value Hₘᵢₙ for the measured flow rate;
in response to determining that the applied H pressure value is less than Hₘᵢₙ, increasing the at least one pump speed nₚᵤₘₚ; and
in response to determining that the applied H pressure value is not less than Hₘᵢₙ, maintaining the previous at least one pump speed nₚᵤₘₚ.

10. The liquid cooling method of claim 1, wherein the controlling of the at least one pump speed further comprises:
in response to determining that the measured flow rate has not increased, determining whether the flow rate remains the same and if not, then incrementally decrease the at least on pump speed nₚᵤₘₚ;
in response to determining that the flow rate has not decreased, continue to incrementally decrease the at least on pump speed nₚᵤₘₚ;
in response to determining that the flow rate has decreased, incrementally increase the pump speed nₚᵤₘₚ.

11. The liquid cooling method of claim 1, wherein the controlling of the at least one pump speed further comprises:
applying a pump head H pressure value to the at least one pump corresponding to the measured flow rate;
determining whether the applied H pressure value is less than a prescribed minimum H pressure value Hₘᵢₙ for the measured flow rate;
in response to determining that the applied H pressure value is less than Hₘᵢₙ, increasing the at least one pump speed nₚᵤₘₚ; and
in response to determining that the applied H pressure value is not less than Hₘᵢₙ, maintaining the previous at least one pump speed nₚᵤₘₚ.

12. A liquid cooling system for rack-mounted processing assemblies, comprising:
a dry cooling unit configured to supply a cooling liquid to the rack-mounted processing assemblies and receive a heated liquid from the rack-mounted processing assemblies, the dry cooling unit comprising a fan assembly and a heat exchanger unit;
a first liquid distribution circuit configured to convey the cooling liquid from the dry cooling unit to the rack-mounted processing assemblies, the first liquid distribution circuit incorporating at least one pump along the first liquid distribution circuit to provide a pressure flow in supplying the cooling liquid from the dry cooling unit to the rack-mounted processing assemblies;
a second liquid distribution circuit configured to convey the heated liquid from the rack-mounted processing assemblies to the dry cooling unit;
each of the rack-mounted data processing assemblies comprising:
at least one heat-generating electronic processing element,
at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and
a smart control valve respectively arranged to be fluidly-coupled to the at least one liquid cooling block of the corresponding rack-mounted data processing assembly, the smart control valve configured to be pressure independent and controls the flow rate of the cooling fluid of the corresponding rack-mounted data processing assembly based on detected temperatures and pressure flows;
the first liquid distribution circuit including a first temperature sensor configured to measure a temperature of the supplied cooling liquid T_{C} and a volume sensor to measure a flow rate of the supplied cooling liquid V_{C};
the second liquid distribution circuit including a second temperature sensor configured to measure a temperature of the returned heated cooling liquid T_{H};
a third temperature sensor configured to measure an ambient temperature of the dry cooling unit T_{DC}; and
a control module, communicatively coupled to the fan assembly and the at least one pump, the control module configured to:
receive the measured T_{C},V_{C}, T_{H}, and T_{DC} values;
estimate a power consumption of the rack-mounted data processing assemblies by calculating a thermal load Q of the first liquid distribution circuit based on the measured T_{C}, T_{H}, and T_{DC} values;
control a speed of the fan assembly based on the estimated power consumption and/or ambient conditions;
determine whether the flow rate has increased based on the measured V_{C} value; and
control a speed of the at least one pump based on whether the flow rate has increased.

13. The liquid cooling system of claim 12, wherein the control of the fan assembly speed by the control module further comprises:
evaluating the ambient temperature of the dry cooling unit T_{DC}, a current fan speed value n_{fan}, and estimated fan power consumption value Q_{fan-est};
operating the fan assembly speed at the current fan speed value n_{fa}, and measuring actual power consumed by the fan assembly Q_{fan-real};
determining whether the actual power consumed by the fan assembly Q_{fan-real} is greater than the estimated fan power consumption value Q_{fan-est} and a tolerance factor K_{factor} and
in response to determining that Q_{fan-real} is greater than Q_{fan-est} and K_{factor}, issuing an alert message indicating that the fan assembly is overconsuming power.

14. The liquid cooling system of claim 12, wherein the control of the at least one pump speed by the control module further comprises:
in response to determining that the flow rate has increased, incrementally increasing the at least on pump speed nₚᵤₘₚ;
determining whether the flow rate has remained the same after increasing the at least one pump speed nₚᵤₘₚ;
in response to determining that the flow rate has not increased, continue to incrementally increase the at least on pump speed nₚᵤₘₚ;
in response to determining that the flow rate is not the same, decreasing the pump speed and after an operating wait time period t, decreasing the pump speed again;
determining whether the flow rate based on the decreased pump speed is less than the previous flow rate;
in response to determining that the flow rate based on the decreased pump speed is not less than the previous flow rate, continue decreasing the pump speed;
upon determining that the flow rate based on the decreased pump speed is less than the previous flow rate, increase the pump speed and select and apply a pump head H pressure value to the at least one pump corresponding to the measured flow rate;
determining whether the applied H pressure value is less than a prescribed minimum H pressure value Hₘᵢₙ for the measured flow rate;
in response to determining that the applied H pressure value is less than Hₘᵢₙ, increasing the at least one pump speed nₚᵤₘₚ; and
in response to determining that the applied H pressure value is not less than Hₘᵢₙ, maintaining the previous at least one pump speed nₚᵤₘₚ.

15. The liquid cooling system of claim 12, wherein the control of the at least one pump speed by the control module further comprises:
in response to determining that the measured flow rate has not increased, determining whether the flow rate remains the same and if not, then incrementally decrease the at least on pump speed nₚᵤₘₚ;
in response to determining that the flow rate has not decreased, continue to incrementally decrease the at least on pump speed nₚᵤₘₚ;
in response to determining that the flow rate has decreased, incrementally increase the pump speed nₚᵤₘₚ;
applying a pump head H pressure value to the at least one pump corresponding to the measured flow rate;
determining whether the applied H pressure value is less than a prescribed minimum H pressure value Hₘᵢₙ for the measured flow rate;
in response to determining that the applied H pressure value is less than Hₘᵢₙ, increasing the at least one pump speed nₚᵤₘₚ; and
in response to determining that the applied H pressure value is not less than Hₘᵢₙ, maintaining the previous at least one pump speed nₚᵤₘₚ.
